(19) United States
(12) Patent Application Publication
(10) Pub. No.: US 2004/0180538 A1
(43) Pub. Date: Sep. 16, 2004

(54) Method for producing a copper connection

(76) Inventor: Paul Rich, Gloucestershire (GB)

Correspondence Address: Volentine Francos, Suite 150, 12200 Sunrise Valley Drive, Reston, VA, 20191, US

(21) Appl. No.: 10/483,046

(22) PCT Filed: May 29, 2002
(86) PCT No.: PCT/GB02/02600

(30) Foreign Application Priority Data
Jul. 14, 2001 (GB) 0117250.1

(51) Int. Cl. H01L 21/4763

(52) U.S. Cl. 438/637

(57) ABSTRACT

A method of forming a conductive interconnect in a semiconductor structure. The method involves forming a via or trench through an interlayer dielectric to lie above prior metallisation. The base of the via or trench is sputter etch cleaned to expose a conductive surface of the prior metallisation. The via or trench is then filled with metal. Prior to the sputter etch step, the surface of the wall or walls of the via or trench are chemically modified to form a surface resistant to metal penetration.

This invention relates to a method of forming a conductive interconnect in a semiconductor structure.

WO-A-00/07236 describes the formation of conductive interconnects in a damascene process environment and in particular notes the problems that can arise when the surface of the buried metal line or via is sputter etch cleaned to remove any oxide and/or etch stop layer. The impact of the sputter ions almost inevitably causes re-deposition of the cleaned material onto the surface of the via that has been formed in a dielectric interlayer. In the case of copper, this can be particularly detrimental because the copper, due to its high mobility, frequently penetrates into the interlayer dielectric and is known to cause via to via leakage current paths. The patent application proposes three solutions to the problem all of which involve the walls of the via being coated with either a barrier layer or an anti-diffusion layer. These coating processes have the disadvantage that they reduce the cross-section of what is already, these days, a very narrow via and they can add significantly to the resistivity of the via.

From one aspect the invention consists in a method of forming a conductive interconnect in a semiconductor structure, comprising forming a via or trench through an interlayer dielectric to lie above prior metallisation, sputter etch cleaning the base of the via or trench to expose a conductive surface of the prior metallisation and filling the via or trench with metal characterized in that prior to the sputter etch step the surface of the wall or walls of the via or trench are chemically modified to form a surface resistant to metal penetration.

By chemically modifying the actual wall or walls of the via or trench there is no reduction in the cross-section nor any increase in the resistivity of the eventually formed via.

The form of chemical modification will of course depend on the chemical nature of the inter-dielectric layer but typically the wall or walls can be nitrided or carbided, so that, for example, where the inter-dielectric layer is a silicon containing material the surface of the wall can be changed to silicon nitride or silicon carbide.

Where a damascene process is being utilised, there will generally be an etch stop layer prior deposited over the prior metallisation in order to indicate to the processor when the etching of the via or trench should stop. It is preferred that the etch stop layer should be of a material which is substantially impervious to the chemical modification process. Thus the etch stop layer could conveniently be silicon nitride or silicon carbide.

Re-sputtering of the material will still occur during the sputter edge clean, but that material will be safely retained on the chemically modified wall. However, to avoid any oxidation of the metal in that re-sputtered material, the via or trench is preferably not exposed to atmosphere between the sputter edge cleaning step and the filling of the via.

Although the invention has been described above it is to be understood it includes any inventive combination of the features set out above or in the following description.

The invention may be performed in various ways and a specific embodiment will now be described with reference to the accompanying drawings, in which:

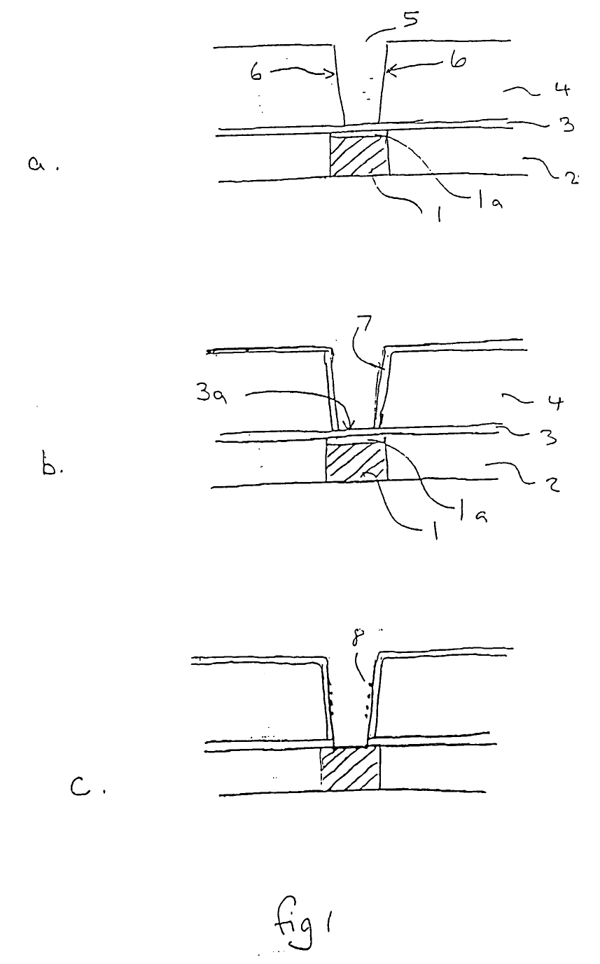

FIG. 1a is a scrap cross-section through a semiconductor structure at a via location immediately after the via has been etched;

FIG. 1b is the corresponding cross-section showing the subsequent chemical modification of the wall of the via; and

FIG. 1c is the corresponding via after a sputter etch clean step has taken place.

In FIG. 1a a semiconductor structure has been formed in which a buried copper line or via 1 has been formed by means of a damascene process, within a dielectric layer 2. The copper line 1 has an oxide layer 1a upon it and an etch stop/diffusion barrier layer 3 may conveniently also have been deposited over the surface of the metal 1 and the dielectric layer 2. A further interlayer dielectric 4 has then been deposited on top of the layer 3 and a via 5 has been etched therethrough to lie above the metal line 1. The via has an exposed side wall 6. If a trench is being etched and filled as in a dual damascene process the, there will of course be two walls.

Turning to FIG. 2 it will be seen that the side wall 6, and consequently the upper surface of the dielectric layer 4, have been chemically modified to form a surface layer 7. It should be appreciated that this process is solely a chemical modification process and not a deposition process. I.e. there is no significant dimensional change to the via.

Preferably this surface layer modification is carried out within the etch apparatus that has etched the via 5 or alternatively it could be carried out in a sputter system which is to be used for the sputter clean step and/or the sputter deposition step (each of which will be described below). Particularly conveniently the sputter wall 6 may be nitrided, for example by exposing the interlayer dielectric 4 to ammonia. If, as is typical, this layer 4 is silicon dioxide, then the ammonia will convert the surface to silicon nitride.

It will be appreciated that if, as has been suggested, the etch stop layer 3 is silicon nitride or silicon carbide, then that will be unchanged by the exposure to ammonia. It is useful to preserve the integrity of this layer during the chemical modification of the surface, because that prevents the risk of any copper poisoning of the dielectric layer 4 prior to the formation of the protective surface layer 7.

In an exemplary process the surface nitride layer is formed using an ammonia plasma at 500 millitorr to convert the silicon dioxide surface of the interlayer dielectric 4.

As is then shown in FIG. 1c the etch stop layer 3 and the oxide layer 1a are sputter etch cleaned to fully expose the metal line 1 at the bottom of the via 5. Conveniently such a sputter etch can be formed using Argon at 2 millitorr with a high substrate bias voltage (e.g. −400 volts). A high plasma density system such an inductively coupled RF system would preferably be used. During the sputter etch clean some copper will be re-sputtered into the via, but as can be seen at 8 it is safely held on the surface 7. This copper 8 could become oxidised if exposed to oxygen and it is therefore preferred that the semiconductor structure is maintained in a vacuum until the via has been filled with metal by electroplating, sputtering or other appropriate process.

1. A method of forming a conductive interconnect in a semiconductor structure comprising forming a via or trench through an interlayer dielectric to lie above prior metallisation, sputter etch cleaning the base of the via or trench to expose a conductive surface of the prior metallisation and filling the via or trench with metal characterised in that prior to the sputter etch step the surface of the wall or walls of the via or trench are chemically modified to form a surface resistant to metal penetration.

2. A method as claimed in claim 1 wherein the surface of the wall or walls are nitrided.

3. A method as claimed in claim 2 wherein the surface of the wall or walls are nitrided by exposure to N₂ or NH₄.

4. A method as claimed in claim 1 wherein the surface of the wall or walls are carbided.

5. A method as claimed in any one of the preceding claims wherein there is an etch stop layer over the prior metallisation and wherein the material of the etch stop layer is substantially impervious to the chemical modifying process.

6. A method as claimed in claim 5 wherein the etch stop layer is silicon nitride or silicon carbide.

7. A method as claimed in any one of the preceding claims wherein the via or trench is not exposed to atmosphere between the sputter etch cleaning step and the filling of the via.
